(19) United States
(12) Patent Application Publication
(10) Pub. No.: US 2016/0033842 A1
(43) Pub. Date: Feb. 4, 2016

(54) DISPLAY PANEL AND MANUFACTURING METHOD THEREOF, AND DISPLAY DEVICE

(71) Applicant: BOE TECHNOLOGY GROUP CO., LTD., Beijing (CN)

(72) Inventors: Yue SHI, Beijing (CN); Jaegeon YOU, Beijing (CN)

(21) Appl. No.: 14/422,205

(22) PCT Filed: Jun. 12, 2014
(86) PCT No.: PCT/CN2014/079744

§ 371 Date: Feb. 18, 2015

(30) Foreign Application Priority Data
Nov. 6, 2013 (CN) 201310546145.7

(51) Int. Cl. G02F 1/163; G03F 7/00; G02F 1/1333; G02F 1/157; G02F 1/17

(52) U.S. Cl. CPC G02F 1/163; G02F 1/157; G02F 1/17; G02F 1/1333; G03F 7/0007; G02F 2001/133357

(57) ABSTRACT

The present invention provides a display panel and a manufacturing method thereof and a display device, the display panel comprises an array substrate and an opposite substrate, the display panel further comprises: an electrochromic structure provided on the array substrate or the opposite substrate, which is used to absorb leakage light of the display panel when the display panel is in a dark state. When the display panel is in a bright state, the electrochromic structure exhibits a transparent state, and when the display panel is in a dark state, the electrochromic structure exhibits a coloring state, the electrochromic structure exhibiting the coloring state may absorb light, so that the leakage light of the display panel in the dark state may be reduced to a largest extent, thus the smallest brightness of the display panel is decreased, therefore, the contrast of the display panel is effectively increased.

### FIELD OF THE INVENTION

The invention relates to the field of display technology, and particularly to a display panel and a manufacturing method thereof, and a display device.

### BACKGROUND OF THE INVENTION

With the developments of science and technology and the progress of the society, liquid crystal display has been more and more widely used by the people, and plays an important role in industrial production and people's life. Currently, high quality liquid crystal display is becoming more and more popular. Many enterprises in the display technology field have invested a lot of manpower and material resources in display device with high contrast, fast response, and low power consumption.

The contrast of a liquid crystal display device refers to a ratio between the largest brightness and the smallest brightness obtained during the display process of the liquid crystal display device. Therefore, the contrast of the liquid crystal display device is associated with the largest brightness when the display device is in a bright state and the smallest brightness when the display device is in a dark state. Usually, in order to enhance the contrast, researchers often achieve this in two aspects of improving the largest brightness and decreasing the smallest brightness.

In the prior art, in the aspect of improving the largest brightness, researchers typically use measures of increasing the aperture ratio of the display panel to improve the largest brightness of the display device. In the aspect of decreasing the smallest brightness, researchers typically use measures of optimizing the cell process of the display panel to reduce the smallest brightness of the display device, for example, using liquid crystals with high scattering coefficient, optimizing the rubbing process in the Cell process or optimizing the cell gap.

However, in the aspect of improving the largest brightness, increasing the aperture ratio can merely improve the largest brightness of the display device to a certain extent, and some new problems relating to process and design will occur during the course of increasing the aperture ratio. In addition, in the aspect of reducing the smallest brightness, when the Cell process is optimized, the adopted solutions are relatively complicated. In summary, technical measures adopted to improve the contrast of the display device in the prior art are complicated, and difficult to realize.

### SUMMARY OF THE INVENTION

The present invention provides a display panel and a manufacturing method thereof, and a display device, which can effectively improve the contrast of the display device through simple technical measures.

In order to realize the above object, the invention provides a display panel, which comprises an array substrate and an opposite substrate, wherein the display panel further comprises an electrochromic structure provided on the array substrate or the opposite substrate, and the electrochromic structure is used to absorb leakage light of the display panel when the display panel is in a dark state.

Optionally, the opposite substrate comprises a first base substrate and a color filter, wherein the color filter is formed on the first base substrate, and wherein when the electrochromic structure is on the opposite substrate, the electrochromic structure is formed on the color filter.

Optionally, the opposite substrate further comprises: a planarization layer formed between the electrochromic structure and the color filter.

Optionally, the electrochromic structure comprises multiple electrochromic subunits;

the color filter comprises color matrix patterns and black matrixes, wherein the black matrixes define pixel regions, and the color matrix patterns are formed in the pixel regions,

wherein the electrochromic subunits are provided so as to correspond to the pixel regions one-to-one.

In order to realize the above object, the invention further provides a display device comprising the above display panel.

In order to realize the above object, the invention further provides a manufacturing method of a display panel, comprising forming an array substrate and an opposite substrate, wherein the manufacturing method further comprises following step:

forming an electrochromic structure on the array substrate or the opposite substrate, wherein the electrochromic structure is used to absorb light leaked from the display panel when the display panel is in a dark state.

Optionally, the step of forming the opposite substrate comprises: forming a first base substrate; and forming a color filter on the first base substrate, and

when the electrochromic structure is formed on the opposite substrate, the step of forming the electrochromic structure comprises: forming the electrochromic structure on the color filter.

Optionally, between the step of forming the color filter on the first base substrate and the step of forming the electrochromic structure on the color filter, the manufacturing method further comprises following step:

forming a planarization layer on the color filter.

Optionally, the electrochromic structure comprises multiple electrochromic subunits, the color filter is formed to include color matrix patterns and black matrixes, and the color matrix patterns are formed in pixel regions.

After the step of forming the electrochromic structure on the color filter, the manufacturing method further comprises following step:

performing a patterning process on the electrochromic structure to form multiple electrochromic subunits so that the electrochromic subunits are provided so as to correspond to the pixel regions one-to-one.

The present invention has following advantages:

The present invention provides a display panel and a manufacturing method thereof, and a display device, the display panel comprises an electrochromic structure, when the display panel is in a bright state, the electrochromic structure exhibits a transparent state, and when the display panel is in a dark state, the electrochromic structure exhibits a coloring state, and the electrochromic structure exhibiting the coloring state may absorb light, so that the leakage light of the display panel in the dark state may be reduced to a largest extent, thus the smallest brightness of the display panel is decreased, therefore, the contrast of the display panel is effectively increased.

### BRIEF DESCRIPTION OF THE DRAWINGS

FIG. 1 is a structural diagram of a display panel provided in an embodiment 1 of the invention;

FIG. 2a is a structural diagram of an opposite substrate in FIG. 1;

FIG. 2b is diagram illustrating the leakage light being absorbed by the electrochromic structure on the opposite substrate in FIG. 2a;

FIG. 3 is a structural diagram of a display panel provided in an embodiment 2 of the invention;

FIG. 4 is a structural diagram of a display panel in which electrochromic subunits are provided corresponding to pixel regions;

FIG. 5 is a flowchart of a manufacturing method of the display panel in FIG. 4;

FIG. 6a is diagram illustrating forming black matrixes and color matrix patterns on a first base substrate;

FIG. 6b is diagram illustrating forming a planarization layer on the black matrixes and the color matrix patterns;

FIG. 6c is diagram illustrating forming a first transparent electrode on the planarization layer;

FIG. 6d is diagram illustrating forming an electrochromic layer on the first transparent electrode; and

FIG. 6e is diagram illustrating forming an orientation layer on a second transparent electrode.

### DETAILED DESCRIPTION OF THE EMBODIMENTS

In order to make persons skilled in the art better understand solutions of the present invention, a display panel and a manufacturing method thereof, and a display device provided in the present invention will be described in detail below in conjunction with the drawings.

### Embodiment 1

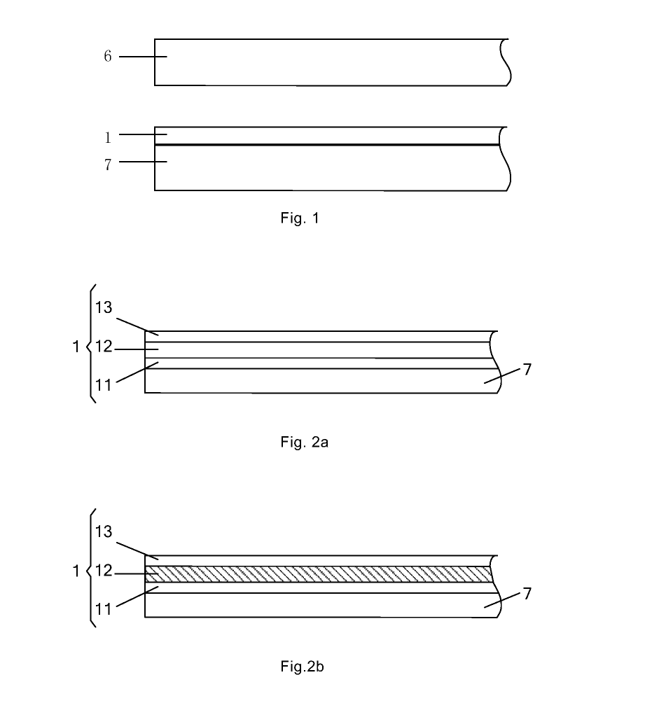

FIG. 1 is a structural diagram of a display panel provided in an embodiment 1 of the invention, FIG. 2a is a structural diagram of an opposite substrate in FIG. 1, and FIG. 2b is diagram illustrating the leakage light being absorbed by the electrochromic structure on the opposite substrate in FIG. 2a. As shown in FIG. 1, FIG. 2a and FIG. 2b, the display panel comprises an array substrate 6, an opposite substrate 7 and an electrochromic structure 1, wherein the electrochromic structure 1 is used to absorb leakage light of the display panel when the display panel is in a dark state.

It should be noted that, the electrochromic structure 1 comprises: a electrochromic layer 12, a first transparent electrode 11 and a second transparent electrode 13, the electrochromic layer 12 is provided between the first transparent electrode 11 and the second transparent electrode 13, and optionally, both of the first transparent electrode 11 and the second transparent electrode 13 are made of tin indium oxide (ITO).

In the present invention, the contrast of the display panel is increased by reducing the smallest brightness of the display panel, and the principle of the invention will be described in detail below.

Optionally, the electrochromic structure 1 is provided on the array substrate 6 or the opposite substrate 7, as shown in FIG. 2, the electrochromic structure 1 is provided on the opposite substrate 7. When the display panel exhibits a bright state, a driving chip drives the first transparent electrode 11 and the second transparent electrode 13 so as to generate a first voltage difference between the first transparent electrode 11 and the second transparent electrode 13, under the action of the first voltage difference, the electrochromic layer 12 exhibits a transparent state, at this time, the whole electrochromic structure 1 also exhibits a transparent state, light emitted from a light source may transmit through the electrochromic structure 1 and thus the display panel may exhibit the largest brightness.

When the display panel exhibits a dark state, a driving chip drives the first transparent electrode 11 and the second transparent electrode 13 so as to generate a second voltage difference between the first transparent electrode 11 and the second transparent electrode 13, under the action of the second voltage difference, the electrochromic layer 12 exhibits a coloring state, at this time, the whole electrochromic structure 1 exhibits a coloring state, the electrochromic structure 1 exhibiting the coloring state may absorb light, which may effectively prevent the light leakage phenomenon when the display panel is in the dark state from occurring, so that the smallest brightness of the display panel may be reduced.

Since there is no change in the largest brightness of the display panel and the smallest brightness of the display panel is reduced, the contrast of the display panel is increased.

The electrochromic layer 12 may be made of organic electrochromic material, inorganic electrochromic material or organic-inorganic hybrid elecrochromic material. Specifically, the organic electrochromic material may include polythiophene and its derivatives, viologen, tetrathiafulvalene, metal phthalocyanine compound or polyaniline, and the inorganic electrochromic material may include WO₃, MoO₃, or V₂O₅.

Alternatively, the electrochromic structure may be provided on the array substrate, and the electrochromic structure on the array substrate may also absorb the leakage light of the display panel being in the dark state, which will not be described here.

It should be noted that, in the present embodiment, the electrochromic structure 1 is provided on a front surface of the opposite substrate 7 (that is, a surface of the opposite substrate 7 facing towards the array substrate after being assembled) or a rear surface of the opposite substrate 7. In the structural diagrams in FIG. 2, the electrochromic structure 1 is provided on the front surface of the opposite substrate 7, and a case of the electrochromic structure 1 being provided on the rear surface of the opposite substrate 7 is not shown in the drawings. In the present embodiment, the electrochromic structure 1 is used to enable light to transmit or absorb light, therefore, whether the electrochromic structure 1 is provided on the front surface or the rear surface of the opposite substrate 7 will not affect its function.

The embodiment 1 of the present invention provides a display panel, the display panel comprises an electrochromic structure, when the display panel is in a bright state, the electrochromic structure exhibits a transparent state, and when the display panel is in a dark state, the electrochromic structure exhibits a coloring state, the electrochromic structure exhibiting the coloring state may absorb light, so that the leakage light of the display panel in the dark state may be reduced to a largest extent, thus the smallest brightness of the display panel is decreased, therefore, the contrast of the display panel is effectively increased.

### Embodiment 2

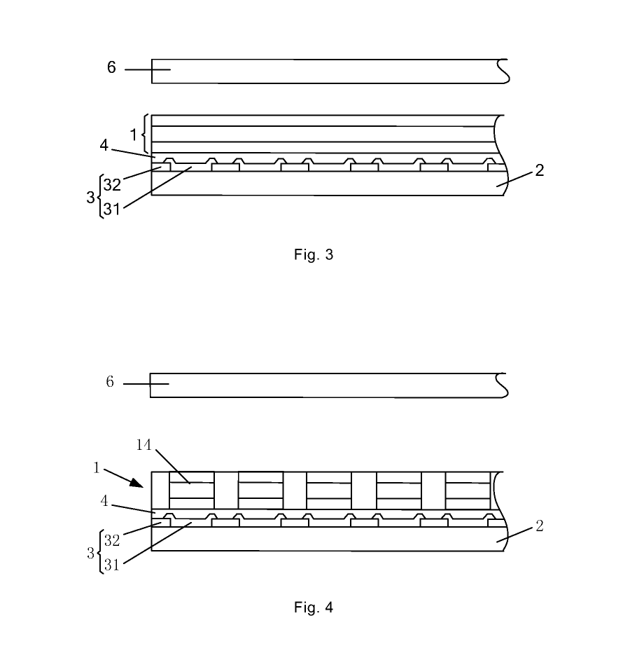

FIG. 3 is a structural diagram of a display panel provided in an embodiment 2 of the invention, and as shown in FIG. 3, the display panel comprises an array substrate 6 and an opposite substrate 7, wherein the opposite substrate 7 includes a first base substrate 2. The electrochromic structure 1 is provided on the opposite substrate, specifically, the electrochromic structure 1 is provided on a front surface of the first base substrate 2, the front surface of the first base substrate 2 is further provided with a color filter 3 thereon, wherein the color filter 3 includes color matrix patterns 31 and black matrixes 32, the black matrixes 32 define pixel regions, the color matrix patterns 31 are formed in the pixel regions, and the electrochromic structure 1 is formed on the color filter 3.

It should be noted that, the present embodiment is different from the embodiment 1 in that, in the present embodiment, the electrochromic structure 1 is formed on the color filter 3. However, regardless of the electrochromic structure 1 being formed on the color filter 3 or directly formed on the first base substrate 2, the smallest brightness of the display panel in the dark state will be reduced.

When the electrochromic structure 1 is formed on the color filter 3, since a surface of the color filter 3 consisting of the color matrix patterns 31 and the black matrixes 32 is not flat, optionally, a planarization layer 4 is formed between the electrochromic structure 1 and the color filter 3, providing the planarization layer 4 may facilitate the formation of the electrochromic structure 1.

FIG. 4 is a structural diagram of a display panel wherein electrochromic subunits are provided corresponding to pixel regions, and as shown in FIG. 4, the electrochromic structure 1 includes multiple electrochromic subunits 14, which are provided in one-to-one correspondence with the pixel regions. When the electrochromic structure 1 is being formed, the electrochromic structure 1 may be an integral structure, size of which is equal to that of the surface of the first base substrate 2, alternatively, a patterning process may be performed on the integral structure so that the electrochromic structure 1 becomes a discrete structure consisting of multiple electrochromic subunits 14 which are provided in one-to-one correspondence with the pixel regions, that is, there is one electrochromic subunit 14 on each pixel region. Since when the display panel is displaying, light is only emitted from pixel regions, and there is no light emitted from regions covered by the black matrixes 32, therefore, only by providing the electrochromic subunits 14 in one-to-one correspondence with the pixel regions, a high contrast of the display panel may be realized.

Optionally, an orientation layer is provided on the topmost layer of the opposite substrate, and the orientation layer is not shown in the drawings.

It should be noted that, when the electrochromic structure is provided on the opposite substrate, the first transparent electrode or the second transparent electrode in the electrochromic structure may be multiplexed as a common electrode, and the common electrode cooperates with the pixel electrode on the array substrate to drive liquid crystals to deflect.

In addition, when the electrochromic structure is provided on the array substrate 6, the array substrate includes: a second base substrate, wherein the second base substrate is formed with gate lines and data lines thereon, the gate lines and the data lines define pixel units. Since both of the gate lines and the data lines are conductive, and both of the first transparent electrode and the second transparent electrode in the electrochromic structure are conductive, when the electrochromic structure is adjacent to the gate lines or the data lines, it is required to form an insulation layer between the electrochromic structure and the gate lines or the data lines.

In addition, when the electrochromic structure is provided on the array substrate 6, the first transparent electrode or the second transparent electrode in the electrochromic structure may be multiplexed as a pixel electrode, and the pixel electrode cooperates with the common electrode to drive liquid crystals to deflect.

The embodiment 2 of the present invention provides a display panel, the display panel comprises an electrochromic structure, when the display panel is in a bright state, the electrochromic structure exhibits a transparent state, and when the display panel is in a dark state, the electrochromic structure exhibits a coloring state, the electrochromic structure exhibiting the coloring state may absorb light, so that the leakage light of the display panel in the dark state may be reduced to a largest extent, thus the smallest brightness of the display panel is decreased, therefore, the contrast of the display panel is effectively increased.

### Embodiment 3

The embodiment 3 of the present invention provides a display device comprising the display panel in the above embodiment 1 or embodiment 2, and specification may refer to the above embodiment 1 or embodiment 2, and will not repeatedly described here.

The display device may be any product or part which is provided with display function such as a mobile phone, a tablet computer, a TV, a display, a notebook computer, a digital image frame, a navigator and the like.

The embodiment 3 of the present invention provides a display device, which comprises a display panel, the display panel is formed with an electrochromic structure, when the display panel is in a bright state, the electrochromic structure exhibits a transparent state, and when the display panel is in a dark state, the electrochromic structure exhibits a coloring state, the electrochromic structure exhibiting the coloring state may absorb light, so that the leakage light of the display panel in the dark state may be reduced to a largest extent, thus the smallest brightness of the display panel is decreased, therefore, the contrast of the display panel is effectively increased.

### Embodiment 4

The present embodiment 4 provides a manufacturing method of a display panel, the manufacturing method comprises:

Step S1, forming an electrochromic structure, wherein the electrochromic structure is used to absorb leakage light of the display panel when the display panel is in a dark state.

Specifically, the step S1 comprises:

Step S101, forming the electrochromic structure on an array substrate or an opposite substrate.

The embodiment 4 of the present invention provides a manufacturing method of a display panel, during manufacturing the display panel, the electrochromic structure is formed on the first base substrate, when the display panel is in a bright state, the electrochromic structure exhibits a transparent state, and when the display panel is in a dark state, the electrochromic structure exhibits a coloring state, the electrochromic structure exhibiting the coloring state may absorb light, so that the leakage light of the display panel in the dark state may be reduced to a largest extent, thus the smallest brightness of the display panel manufactured by the manufacturing method in the present embodiment is decreased, therefore, the contrast of the display panel is effectively increased.

### Embodiment 5

The embodiment 5 of the present invention provides a manufacturing method of a display panel, wherein, the electrochromic structure is provided on a front surface of a first base substrate and includes: an electrochromic layer, a first transparent electrode and a second transparent electrode, wherein the front surface of the first base substrate is further provided with a color filter thereon, wherein the color filter includes color matrix patterns and black matrixes, the black matrixes define pixel regions, the color matrix patterns are formed in the pixel regions, and the electrochromic structure is provided on the color filter.

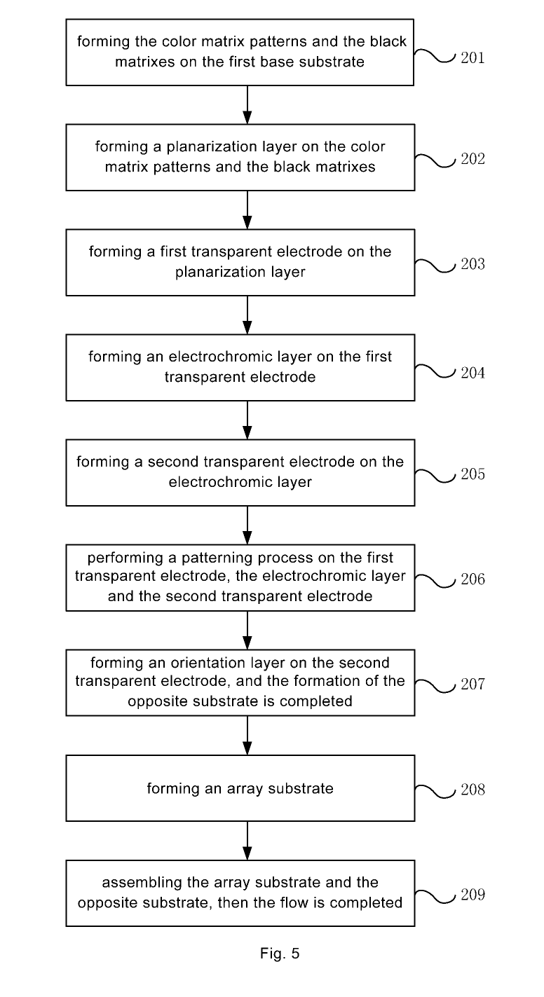

FIG. 5 is a flowchart of a manufacturing method of the display panel in FIG. 4, and as shown in FIG. 5, the manufacturing method comprises:

Step 201, forming the color matrix patterns and black matrixes on the first base substrate.

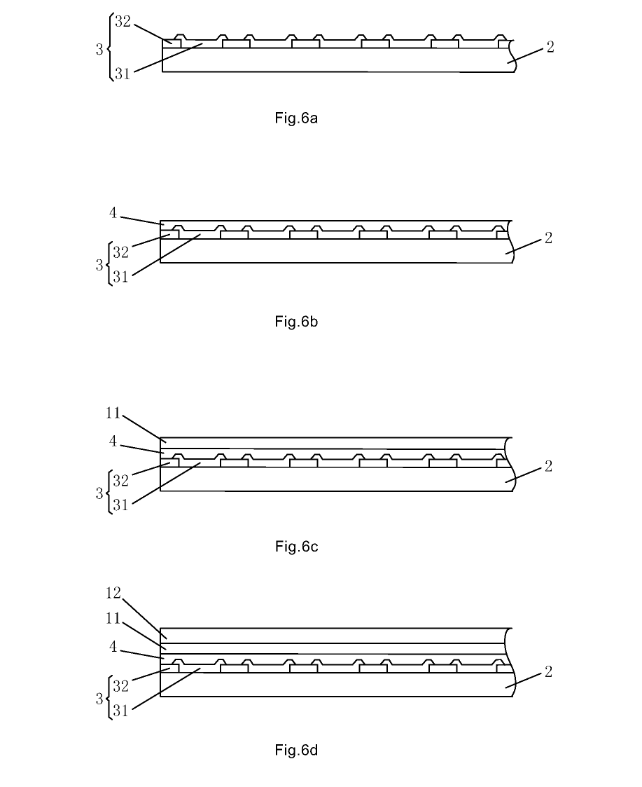

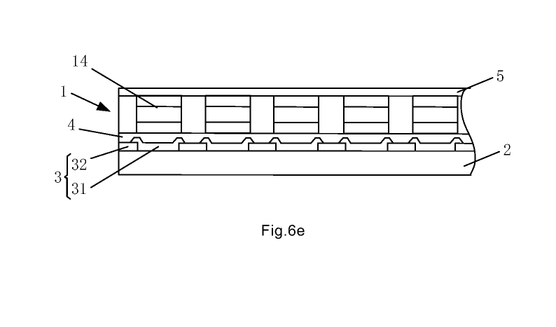

FIG. 6a is diagram illustrating forming black matrixes and color matrix patterns on a first base substrate, and as shown in FIG. 6, first, a layer of base material for the black matrixes is formed on the first base substrate, and then a patterning process is performed on the layer of base material for black matrix to form the black matrixes 32; next, a layer of base material for the color filter is formed on the first base substrate and then a patterning process is preformed on the layer of base material for the color filter to form the color matrix patterns 31, wherein the black matrixes 32 define pixel regions, and the color matrix patterns 31 are provided in the pixel regions.

Step 202, forming a planarization layer on the color matrix patterns and the black matrixes.

FIG. 6b is diagram illustrating forming a planarization layer on the black matrixes and the color matrix patterns, as shown in FIG. 6, since the surface consisting of the color matrix patterns 31 and the black matrixes 32 is not flat, a chemical vapor deposition technology may be adopted to form a planarization layer 4 on the color matrix patterns 31 and the black matrixes 32, the planarization layer 4 may protect the color matrix patterns 31 and the black matrixes 32, and the flat surface of the planarization layer 4 may facilitate the formation of the electrochromic structure.

Step 203, forming a first transparent electrode on the planarization layer.

FIG. 6c is diagram illustrating forming a first transparent electrode on the planarization layer, as shown in FIG. 6c, a layer of first transparent electrode 11 is formed on the planarization layer 4 through the chemical vapor deposition or a megnetron sputtering, and optionally, the first transparent electrode 11 is made of ITO.

Step 204, forming an electrochromic layer on the first transparent electrode.

FIG. 6d is diagram illustrating forming an electrochromic layer on the first transparent electrode, and as shown in FIG. 6d, the first transparent electrode 11 is uniformly formed with a layer of electrochromic material thereon, wherein the layer of electrochromic material is the electrochromic layer 12.

Step 205, forming a second transparent electrode on the electrochromic layer.

As shown in FIG. 2, a second transparent electrode 13 is formed on the electrochromic layer 12 through the chemical vapor deposition or a megnetron sputtering, and optionally, the second transparent electrode is made of ITO.

Step 206, performing a patterning process on the first transparent electrode, the electrochromic layer and the second transparent electrode.

As shown in FIG. 4, after the patterning process is performed on the first transparent electrode 11, the electrochromic layer 12 and the second transparent electrode 13, the electrochromic structure 1 becomes a discrete structure consisting of multiple electrochromic subunits 14, and one electrochromic subunit 14 is correspondingly provided above each pixel region.

It should be noted that, the patterning process in the embodiments of the invention includes part or all of photoresist coating, masking, exposure, development, etching, photoresist peeling off, and the like.

Step 207, forming an orientation layer on the second transparent electrode, and the formation of the opposite substrate is completed.

FIG. 6e is diagram illustrating forming an orientation layer on the second transparent electrode, and as shown in FIG. 6e, a layer of base material for the orientation layer is formed on the second transparent electrode 13 first, and then the layer of base material for the orientation layer is processed through a Rubbing process to form the orientation layer 5.

It should be noted that, if the electrochromic structure 1 is an integral structure, the size of which equals to that of the surface of the first base substrate, after the step 205 is finished, the step 207 is directly performed.

It should be noted that, in the display panel formed in the above sequence, the electrochromic structure is provided above the color filter, and however, the order of steps may be changed in the present embodiment, so that the electrochromic structure is provided between the first base substrate and the color filter.

Step 208, forming an array substrate.

Procedures of forming the array substrate are the same as those in the prior art, which will not repeated here.

Step 209, assembling the array substrate and the opposite substrate, then the flow is completed.

It should be noted that, only a case of the electrochromic structure being provided on the opposite substrate is described in the present embodiment, and a case of the electrochromic structure being provided on the array substrate may be achieved by corresponding modification to the present embodiment.

The embodiment 5 of the present invention provides a manufacturing method of a display panel, during manufacturing the display panel, an electrochromic structure is formed on the opposite substrate, when the display panel is in a bright state, the electrochromic structure exhibits a transparent state, and when the display panel is in a dark state, the electrochromic structure exhibits a coloring state, the electrochromic structure exhibiting the coloring state may absorb light, so that the leakage light of the display panel in the dark state may be reduced to a largest extent, thus the smallest brightness of the display panel manufactured by the manufacturing method in the present embodiment is decreased, therefore, the contrast of the display panel is effectively increased.

It should be understood that, the above embodiments are only exemplary embodiments employed to illustrate the principle of the invention, and the invention is not limited thereto. Persons skilled in the art can make various modifications and improvements without departing from the principle and substance of the invention, and these modifications and improvements should be considered to be within the protection scope of the invention.

1-9. (canceled)

10. A display panel comprising an array substrate and an opposite substrate, wherein the display panel further comprises an electrochromic structure provided on the array substrate or the opposite substrate, and the electrochromic structure is used to absorb leakage light of the display panel when the display panel is in a dark state.

11. The display panel of claim 10, wherein the opposite substrate comprises a first base substrate and a color filter, and the color filter is formed on the first base substrate, and wherein when the electrochromic structure is on the opposite substrate, the electrochromic structure is formed on the color filter.

12. The display panel of claim 11, wherein the opposite substrate further comprises: a planarization layer formed between the electrochromic structure and the color filter.

13. The display panel of claim 11, wherein the electrochromic structure comprises multiple electrochromic subunits;
the color filter comprises color matrix patterns and black matrixes, wherein the black matrixes define pixel regions, and the color matrix patterns are formed in the pixel regions; and
the electrochromic subunits are provided so as to correspond to the pixel regions one-to-one.

14. A display device comprising a display panel of claim 10.

15. The display device of claim 14, wherein the opposite substrate comprises a first base substrate and a color filter, and the color filter is formed on the first base substrate, and wherein when the electrochromic structure is on the opposite substrate, the electrochromic structure is formed on the color filter.

16. The display device of claim 15, wherein the opposite substrate further comprises: a planarization layer formed between the electrochromic structure and the color filter.

17. The display device of claim 15, wherein the electrochromic structure comprises multiple electrochromic subunits;
the color filter comprises color matrix patterns and black matrixes, wherein the black matrixes define pixel regions, and the color matrix patterns are formed in the pixel regions; and
the electrochromic subunits are provided so as to correspond to the pixel regions one-to-one.

18. A manufacturing method of a display panel, comprising forming an array substrate and an opposite substrate, wherein the manufacturing method further comprises following step:
forming an electrochromic structure on the array substrate or the opposite substrate, wherein the electrochromic structure is used to absorb leakage light of the display panel when the display panel is in a dark state.

19. The manufacturing method of a display panel of claim 18, wherein the steps of forming the opposite substrate comprise: forming a first base substrate; and forming a color filter on the first base substrate, and
when the electrochromic structure is formed on the opposite substrate, the step of forming the opposite substrate comprises: forming the electrochromic structure on the color filter.

20. The manufacturing method of a display panel of claim 19, wherein between the steps of forming the color filter on the first base substrate and the step of forming the electrochromic structure on the color filter, the manufacturing method further comprises following step:
forming a planarization layer on the color filter.

21. The manufacturing method of a display panel of claim 19, wherein the color filter is formed to include color matrix patterns and black matrixes, and the color matrix patterns are formed in pixel regions; and
wherein, after the step of forming the electrochromic structure on the color filter, the manufacturing method comprises following step:
performing a patterning process on the electrochromic structure to form multiple electrochromic subunits, so that the electrochromic subunits are provided so as to correspond to the pixel regions one-to-one.
